(19) United States
(12) Patent Application Publication
(10) Pub. No.: US 2026/0064007 A1
(43) Pub. Date: Mar. 5, 2026

(54) EUV LIGHT SOURCE DEVICE FOR EUV MASK INSPECTION

(71) Applicant: ESOL, Inc., Hwaseong-si (KR)

(72) Inventor: Dong Gun LEE, Hwaseong-si (KR)

(73) Assignee: ESOL, Inc., Hwaseong-si (KR)

(21) Appl. No.: 18/904,185

(22) Filed: Oct. 2, 2024

(30) Foreign Application Priority Data
Aug. 30, 2024 (KR) 10-2024-0117951

(51) Int. Cl. G03F 7/00; G03F 1/22; G03F 1/84

(52) U.S. Cl. CPC G03F 7/702; G03F 1/22; G03F 1/84; G03F 7/70033; G03F 7/70175; G03F 7/70891; G03F 7/70916; G03F 7/70925; H05G 2/0023

(57) ABSTRACT

The present disclosure relates to an EUV light source device for EUV mask inspection, including: an IR laser source for emitting an IR laser beam; a condenser lens for collecting the IR laser beam emitted from the IR laser source; a collector mirror having a hole formed at the center thereof in such a way as to pass the IR laser beam collected onto the condenser lens therethrough, the collector mirror being adapted to collect EUV light reflected onto a liquid target if the IR laser beam reacts with the liquid target to produce the EUV light; a target feeder for continuously feeding the liquid target to allow the IR laser beam passing through the hole formed on the collector mirror to react with the liquid target; and a plurality of heaters located on the collector mirror.

### BACKGROUND OF THE DISCLOSURE

### Cross Reference to Related Application of the Disclosure

The present application claims the benefit of Korean Patent Application No.10-2024-0117951 filed in the Korean Intellectual Property Office on Aug. 30, 2024, the entire contents of which are incorporated herein by reference.

### Field of the Disclosure

The present disclosure relates to an extreme ultraviolet (EUV) light source device for EUV mask inspection, more specifically to an EUV light source device for EUV mask inspection that is capable of being applied to equipment for inspecting a circular EUV mask used in an EUV exposure process.

### Background of the Related Art

Recently, an EUV exposure system for manufacturing a semiconductor device using EUV light with a wavelength of 13.5 nm has been actively introduced in a semiconductor manufacturing process. The EUV exposure system makes use of a shorter wavelength than an existing argon fluoride (ArF) exposure system using a wavelength of 193 nm, which is advantageous in the miniaturization of the semiconductor device.

In the future, it is expected that an EUV exposure system having 0.55 numerical aperture (NA) bigger than the present 0.33 NA will be introduced so that a miniaturized pattern having a substantially smaller size could be formed.

Further, there is a possibility that an EUV exposure system making use of EUV light with a wavelength of 6 nm shorter than 13.5 nm in the EUV wavelength range (between 5 and 15 nm) could be introduced in an industrial field.

The EUV exposure system, which is applied to the industrial field, makes use of an EUV mask as a circular mask. The EUV mask is configured differently from a mask of the existing ArF exposure system.

The biggest difference between the EUV mask of the EUV exposure system and the mask of the existing ArF exposure system is that the EUV mask has a reflection structure, not a transmission structure, and further, since the EUV mask has optimized reflectivity in the wavelength of 13.5 nm, the application of the EUV light as a light source of an inspection system is advantageous in achieving high performance of the inspection system.

Among steps in the manufacturing process of the EUV mask, inspection of defect on a pattern of the circular mask and correction of the detected defect are important steps having direct influences on a wafer yield. This is because the defect of the circular mask is repeatedly transferred on all of wafers.

Even though the equipment for inspecting the EUV mask is necessarily needed, however, overall equipment price becomes high and a period of equipment delivery becomes substantially long because of a high development cost of an EUV optical system as a key part of the equipment. Therefore, there is a need to develop an EUV mask inspection system and an EUV light source to which a new EUV optical system is applied so that the number of EUV optical parts is reduced and a manufacturing period of the EUV optical system is shortened.

### Prior Art Literature

### Patent Literature

(Patent literature) U.S. Pat. No. 9,476,841

### SUMMARY OF THE DISCLOSURE

Accordingly, the present disclosure has been made in view of the above-mentioned problems occurring in the related art, and it is an object of the present disclosure to provide an EUV light source device for EUV mask inspection that is needed for an EUV exposure system and an EUV mask inspection system.

It is another object of the present disclosure to provide an EUV light source device for EUV mask inspection that is capable of providing a lithium liquid phase plasma (LPP)-based EUV light source needed for an EUV exposure system and an EUV mask inspection system to which a diffractive optical element is applied.

It is yet another object of the present disclosure to provide an EUV light source device for EUV mask inspection that is capable of optimizing the performance of a collector mirror for collecting EUV light generated from an EUV light source with a high collection efficiency, thereby providing big mass production.

To accomplish the above-mentioned objects, according to the present disclosure, there is provided an EUV light source device for EUV mask inspection, including: an infrared (IR) laser source for emitting an IR laser beam; a condenser lens for collecting the IR laser beam emitted from the IR laser source; a collector mirror having a hole formed at the center thereof in such a way as to pass the IR laser beam collected onto the condenser lens therethrough, the collector mirror being adapted to collect EUV light reflected onto a liquid target if the IR laser beam reacts with the liquid target to produce the EUV light; a target feeder for continuously feeding the liquid target to allow the IR laser beam passing through the hole formed on the collector mirror to react with the liquid target; and a plurality of heaters located on the collector mirror to heat and evaporate liquid target contaminants deposited on the surface of the collector mirror.

According to the present disclosure, desirably, in a single chamber, the collector mirror having the plurality of heaters, the IR laser source, and the liquid target may react with one another to produce laser plasmas.

According to the present disclosure, desirably, the chamber may further include a debris shield for preventing the scattered liquid target contaminants from leaking to the outside of the chamber to provide the EUV light produced through the collector mirror to the outside.

According to the present disclosure, desirably, the target feeder may include: a storage container for storing the liquid target; a pump for pumping and feeding the liquid target stored in the storage container; a transfer pipe for transferring the liquid target pumped through the pump; a plurality of heater bodies for heating the liquid target transferred through the transfer pipe to a given temperature; a nozzle for injecting the liquid target fed through the transfer pipe; and a capturing pipe for capturing the liquid target injected through the nozzle and feeding the captured liquid target to the storage container.

According to the present disclosure, desirably, the target feeder may further include a support body for supporting the liquid target so that the liquid target is injected in a given thickness and position through the nozzle.

According to the present disclosure, desirably, the liquid target may be formed of liquid lithium (Li) or liquid lithium alloy (Li alloy).

According to the present disclosure, desirably, the plurality of heaters may heat the collector mirror to a temperature between 350 and 600° C. so that the liquid target contaminants deposited on the collector mirror are evaporated.

According to the present disclosure, desirably, the EUV light produced from the laser plasmas may spread in a solid angle of a 2 pi steradian (SR) in the opposite direction of the irradiation direction of the IR laser beam, and to collect the EUV light spreading in the 2 pi SR to the maximum, the collector mirror may have an on-axis structure and axial symmetry with the hole formed at the center thereof in such a way as to pass the IR laser beam therethrough.

According to the present disclosure, desirably, the collector mirror may be coated with multilayers for reflecting the EUV light thereon.

According to the present disclosure, desirably, the debris shield may be formed of a thin film containing carbon nanotubes (CNT) or graphene layers made of carbon.

According to the present disclosure, desirably, the nozzle may continuously feed the liquid target in the form of a droplet from top and to bottom.

### BRIEF DESCRIPTION OF THE DRAWINGS

The above and other objects, features and advantages of the present disclosure will be apparent from the following detailed description of the preferred embodiments of the disclosure in conjunction with the accompanying drawings, in which:

FIG. 1 is a schematic diagram showing an EUV light source device for EUV mask inspection according to the present disclosure;

FIG. 2 is a detailed diagram showing the EUV light source device for EUV mask inspection according to the present disclosure;

FIG. 3 is a diagram showing a collector mirror of the EUV light source device for EUV mask inspection according to the present disclosure;

FIG. 4 illustrates side and front views (A)-(D) showing various examples of a target feeder for feeding a liquid target in the EUV light source device for EUV mask inspection according to the present disclosure; and

FIG. 5 illustrates a perspective view (A) and a top view (B) showing the collector mirror provided integrally with heaters in the EUV light source device for EUV mask inspection according to the present disclosure.

### DETAILED DESCRIPTION OF THE PREFERRED EMBODIMENTS

Hereinafter, an explanation of an EUV light source device for EUV mask inspection according to the present disclosure will be given in detail with reference to the attached drawings.

An EUV light source device for EUV mask inspection according to the present disclosure includes: an infrared (IR) laser source for emitting an IR laser beam; a condenser lens for collecting the IR laser beam emitted from the IR laser source; a collector mirror having a hole formed at the center thereof in such a way as to pass the IR laser beam collected onto the condenser lens therethrough, the collector mirror being adapted to collect EUV light reflected onto a liquid target if the IR laser beam reacts with the liquid target to produce the EUV light; a target feeder for continuously feeding the liquid target to allow the IR laser beam passing through the hole formed on the collector mirror to react with the liquid target; and a plurality of heaters located on the collector mirror to heat and evaporate liquid target contaminants deposited on the surface of the collector mirror.

The EUV light source device for EUV mask inspection according to the present disclosure largely includes four parts, an IR laser radiation part, a lithium jet as an IR laser target, a light collecting part for collecting EUV light produced through the interaction between the IR laser and the lithium jet, and a heating part for removing the contaminants of the light collecting unit.

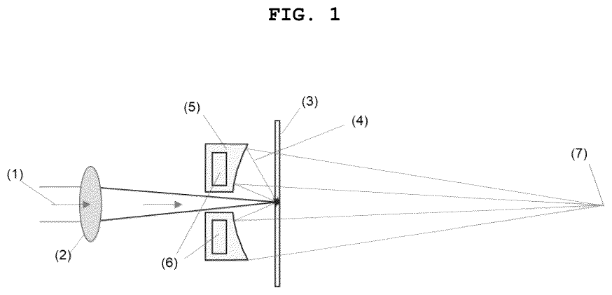

FIG. 1 is a schematic diagram showing an EUV light source device for EUV mask inspection according to the present disclosure.

In detail, the EUV light source device according to the present disclosure includes a laser source 1, a condenser lens 2 for collecting a laser beam generated from the laser source 1, a liquid target 3 fed in the form of a jet to produce laser plasmas from the laser beam emitted from the laser source 1, and a collector mirror 5 for collecting EUV light 4 produced through the laser plasmas.

In this case, according to the main technological parts of the present disclosure, at least one or more heaters 6 are located on the collector mirror 5 to prevent target contaminants generated during the production of the laser plasmas from the liquid target 3 from being contaminatedly deposited on the surface of the collector mirror 5, and therefore, the collector mirror 5 is entirely heated through the heaters 6 to allow the target contaminants deposited thereon to be heated and evaporated, thereby ensuring a high collection efficiency thereof and consistently producing optimal EUV light (with a wavelength between 10 and 14 nm).

The laser source 1 according to the present disclosure is desirably an IR laser source, and when the EUV light 4 produced through the plasma reaction of the liquid target 3 is collected and provided to an application, according to the present disclosure, the EUV light 4 is collected on an on-axis structure and reflected.

To do so, according to the present disclosure, when the EUV light 4 is collected from the plasmas generated through the laser beam irradiated on the lithium target (liquid target 3), the collector mirror 5 is applied to collect the EUV light 4, and according to the present disclosure, a hole is formed on a center of the collector mirror 5 to pass the laser beam to be irradiated to the liquid target 3 therethrough, while the remaining area of the collector mirror 5 is collecting the EUV light generated from the liquid target 3 in a range of a solid angle becoming as large as possible.

As a result, the range of a solid angle capable of collecting the EUV light through the collector mirror 5 is wider than that through an existing off-axis type collector mirror, so that a greater amount of light is transmitted to an optical system of an inspection system or exposure system.

Therefore, the EUV light collected on the collector mirror 5 is finally irradiated as EUV light 7 collected to an application.

The EUV light is emitted from Li plasmas generated when the IR laser is collected onto an Li substance. Such conditions have to be consistently and stably achieved.

According to the present disclosure, the liquid target 3 is provided in the form of a jet so that the Li target is consistently and stably formed. To provide stable Li target conditions, lithium is heated and liquefied, and to allow the lithium liquid having conductivity to be formed as the liquid target in the form of the jet, a pump using the principle of electromagnetic induction is adopted. Using such a pump, a pressure is formed in a liquid lithium pipe, and the jet of the liquid lithium is injected through a nozzle. As a result, the lithium target is consistently formed on a given position to a given thickness.

Further, debris, which is generated when the IR laser beam and the lithium liquid target interact to generate the EUV light, has to be effectively treated. If the debris is collected onto the collector mirror 5, a degree of reflectivity of the collector mirror 5 becomes low, which causes the replacement of the collector mirror 5 or needs a process of removing the debris from the surface of the collector mirror 5.

According to the present disclosure, a special EUV reflection layer resistant to high temperature is coated onto the collector mirror 5, and the collector mirror 5 is raised to a temperature at which lithium is vaporized, so that the surface of the collector mirror 5 is always kept clean.

According to the present disclosure, therefore, the heaters 6 are located on the collector mirror 5 to heat the collector mirror 5 in the range of a temperature at which the liquid target is vaporized, so that the liquid target contaminants deposited on the surface of the collector mirror 5 are removed to achieve stable EUV light production. That is, the heaters 6 transmit heat to the collector mirror 5 itself to allow the contaminants deposited on the surface of the collector mirror 5 to be vaporized and removed.

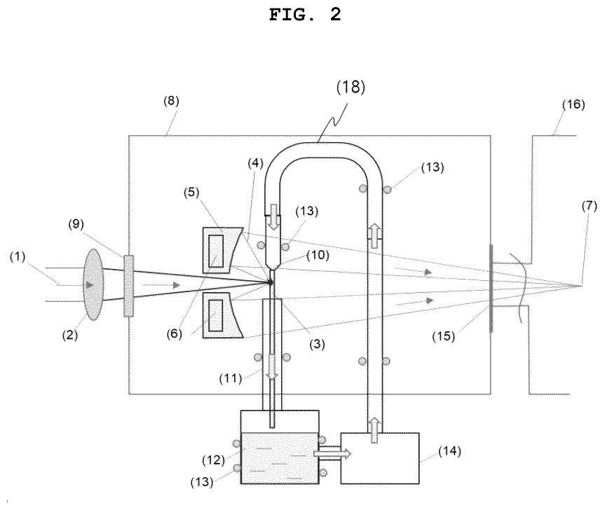

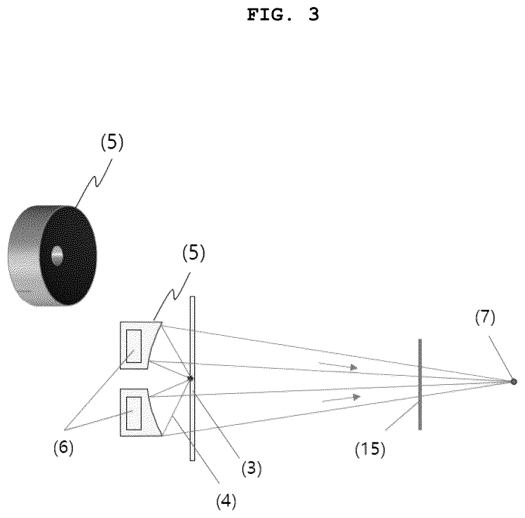

FIG. 2 is a detailed diagram showing the EUV light source device for EUV mask inspection according to the present disclosure, and FIG. 3 is a diagram showing a collector mirror of the EUV light source device for EUV mask inspection according to the present disclosure.

According to the present disclosure, a liquid target feeder for continuously feeding the liquid target in the form of the jet is provided to allow the liquid target to have a given thickness and width and a reaction with the laser plasmas.

As mentioned above, to allow the lithium liquid having conductivity to be formed on a target in the form of the jet, the pump using the principle of electromagnetic induction is adopted. Using such a pump, a pressure is formed in the liquid lithium pipe, and the jet is injected through the nozzle and thus formed. As a result, the lithium target is consistently formed on a given position to a given thickness.

A debris shield 15 is located between the EUV light source device and the optical system of the inspection system or exposure system to shield the debris moving to the optical system of the inspection system or exposure system from the EUV light source device. Generally, the debris shield is formed of a thin film containing carbon nanotubes (CNT) or graphene layers made of carbon, and further, a current flows to the debris shield to remove contaminants therefrom through evaporation.

According to the present disclosure, a target feeder is provided to feed the liquid target 3. The target feeder is a feeding system for continuously feeding the liquid lithium in the form of the jet and includes a storage container 12, a pump 14, a transfer pipe 18, and a nozzle 10.

Further, the target feeder includes a capturing pipe 11 located under the nozzle 10 to capture the liquid lithium injected from the nozzle 10 and heater bodies 13 located on the transfer pipe 18 to allow the liquid lithium to be kept and fed in a liquid state.

As a result, the liquid lithium stored in the storage container 12 is transferred to the transfer pipe 17 through the pump 14 and then injected through the nozzle 10, and in this case, the liquid lithium has a plasma reaction with the collected laser beam to produce EUV light.

According to the present disclosure, desirably, the liquid target 3 is liquid lithium or liquid lithium alloy. To allow the liquid target 3 to be kept in a liquid state, the nozzle 10 and the capturing pipe 11 are kept in the range between 180 and 350° C. by means of respective heaters. A melting point of lithium is 180.5° C.

The liquid target 3 injected through the nozzle 10 is exposed to a vacuum chamber 8, captured through the capturing pipe 11, and collected again to the storage container 12.

In this case, the liquid target 3 injected through the nozzle 10 flows along a support body 17 as a rear wall of the nozzle 10 and is then introduced into the capturing pipe 11. The support body 17 serves to stabilize the thickness or position of the liquid target 3, while the liquid target 3 is flowing therealong.

As a result, the liquid target 3 in the form of the jet is applied to induce the plasma reaction with the laser beam, so that a stable target for a high brightness EUV light source is provided.

Further, the EUV light source device according to the present disclosure is configured to allow the components to be located inside one chamber 8 to produce the EUV light, and the produced EUV light is transmitted and used to an external chamber 16 through the debris shield 15.

That is, the light 7 collected through the collector mirror 5 is transmitted to a place of light use through the debris shield 15, and the debris shield 15 is formed of a thin film containing CNTs or graphene layers made of carbon and kept to a temperature greater than 350° C. with the current flowing thereto to evaporate the lithium contaminants.

The debris shield 15 serves to evaporate the target substance (debris) formed on the surface of the collector mirror 5 heated through the heaters 6, thereby improving the collection efficiency of the collector mirror 5.

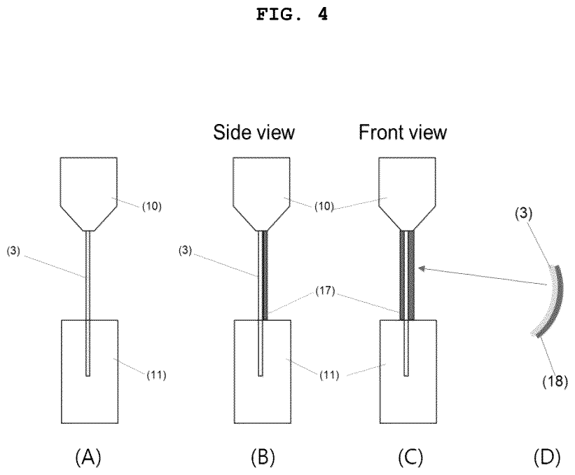

FIGS. 4A to 4D are side and front views showing various examples of the target feeder for feeding the liquid target in the EUV light source device for EUV mask inspection according to the present disclosure.

As mentioned above, the support body 17 is provided to constantly keep the thickness and position of the liquid target 3, while the liquid target 3 is being injected through the nozzle 10. As shown in FIG. 4A, the liquid target 3 injected through the nozzle 10 is introduced directly into the capturing pipe 11, without any support body 17. As shown in FIGS. 4B and 4C, the liquid target 3 injected through the nozzle 10 is introduced into the capturing pipe 11, while flowing along the support body 17. The support body 17 serves as a support for allowing the liquid target 3 to be injected in stabilized position and thickness.

Further, as shown in FIG. 4D, a support body 18 is configured to have a given curvature in a given radius thereof. As a result, the liquid target 3 flows stably along the support body 18 having such a curvature.

According to another embodiment of the present disclosure, further, the liquid target 3 is fed in the form of a droplet. In the above description, an example wherein the liquid target 3 is fed in the form of the jet continuously fed from top to bottom has been explained, but according to another embodiment of the present disclosure, the liquid target 3 having the shape of a small drop of liquid is fed in the form of a droplet continuously fed from top to bottom.

As a result, the liquid target 3 having the shape of the small drop of liquid is continuously dropped through the nozzle 10 from top to bottom. This enables an amount of liquid target 3 injected through the nozzle 10 to be appropriately adjusted to determine the size and feeding speed of the droplet.

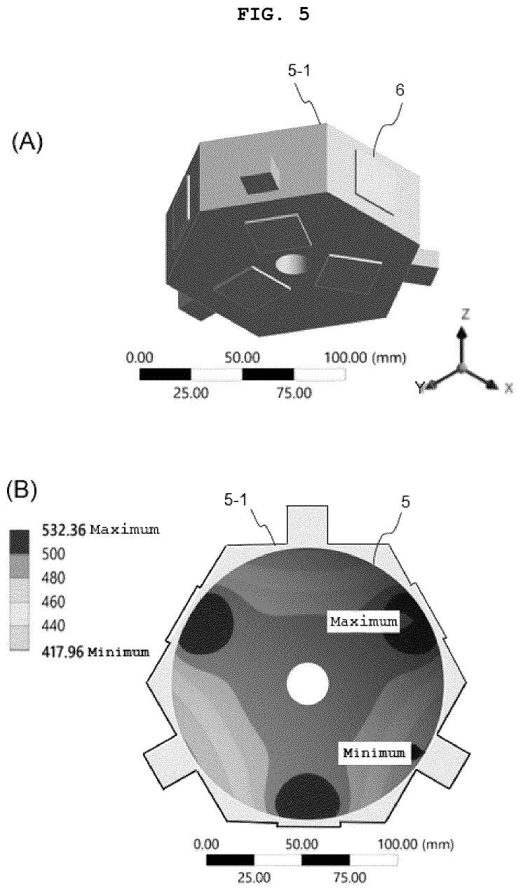

FIGS. 5A and 5B are perspective and top views showing the collector mirror provided integrally with heaters in the EUV light source device for EUV mask inspection according to the present disclosure.

FIGS. 5A and 5B show an example of a mounter 5-1 for mounting the heaters 6 onto the collector mirror 5 according to the present disclosure. First, the mounter 5-1 surrounds the circular collector mirror 50, and next, the plurality of heaters 6 are attached to the surfaces of the mounter 5-1 to transmit heat to the collector mirror 5.

According to the present disclosure, the heat distribution to the collector mirror 5 when heat is applied to the collector mirror 5 through the heaters 6 is measured to thus complete stability estimation. That is, the collector mirror 5 is heated to a temperature between 350 and 600° C. through the heaters 6 so that the deposited liquid target contaminants are evaporated.

As described above, under the above-mentioned configuration of the present disclosure, advantageously, there is provided excellent lithium liquid phase plasma (LPP)-based EUV light source device that is needed for an EUV exposure system and an EUV mask inspection system.

According to the present disclosure, above all, the EUV light source device optimizes the performance of the collector mirror for collecting the EUV light generated from the EUV light source with a high collection efficiency, thereby providing big mass production.

Although specific embodiments have been illustrated and described herein, it will be appreciated by those of ordinary skill in the art that any specific arrangement of software, which is calculated to achieve the same purpose, may be substituted for the specific embodiment shown. This application is intended to cover any adaptations or variations of the present disclosure. Therefore, it is manifestly intended that this disclosure be limited only by the claims and the equivalents thereof.

What is claimed is:

1. An extreme ultraviolet (EUV) light source device for EUV mask inspection, comprising:
an infrared (IR) laser source for emitting an IR laser beam;
a condenser lens for collecting the IR laser beam emitted from the IR laser source;
a collector mirror having a hole formed at the center thereof in such a way as to pass the IR laser beam collected onto the condenser lens therethrough, the collector mirror being adapted to collect EUV light reflected onto a liquid target if the IR laser beam reacts with the liquid target to produce the EUV light;
a target feeder for continuously feeding the liquid target to allow the IR laser beam passing through the hole formed on the collector mirror to react with the liquid target; and
a plurality of heaters located on the collector mirror to heat and evaporate liquid target contaminants deposited on the surface of the collector mirror.

2. The EUV light source device according to claim 1, wherein in a single chamber, the collector mirror having the plurality of heaters, the IR laser source, and the liquid target react with one another to produce laser plasmas.

3. The EUV light source device according to claim 2, wherein the chamber further comprises a debris shield for preventing the scattered liquid target contaminants from leaking to the outside of the chamber to provide the EUV light produced through the collector mirror to the outside.

4. The EUV light source device according to claim 1, wherein the target feeder comprises:
a storage container for storing the liquid target;
a pump for pumping and feeding the liquid target stored in the storage container;
a transfer pipe for transferring the liquid target pumped through the pump;
a plurality of heater bodies for heating the liquid target transferred through the transfer pipe to a given temperature;
a nozzle for injecting the liquid target fed through the transfer pipe; and
a capturing pipe for capturing the liquid target injected through the nozzle and feeding the captured liquid target to the storage container.

5. The EUV light source device according to claim 4, wherein the target feeder further comprises a support body for supporting the liquid target so that the liquid target is injected in a given thickness and position through the nozzle.

6. The EUV light source device according to claim 1, wherein the liquid target is formed of liquid lithium (Li) or liquid lithium alloy (Li alloy).

7. The EUV light source device according to claim 1, wherein the plurality of heaters heat the collector mirror to a temperature between 350 and 600° C. so that the liquid target contaminants deposited on the collector mirror are evaporated.

8. The EUV light source device according to claim 1, wherein the EUV light produced from the laser plasmas spreads in a solid angle of a 2 pi steradian (SR) in the opposite direction of the irradiation direction of the IR laser beam, and to collect the EUV light spreading in the 2 pi SR to the maximum, the collector mirror has an on-axis structure and axial symmetry with the hole formed at the center thereof in such a way as to pass the IR laser beam therethrough.

9. The EUV light source device according to claim 1, wherein the collector mirror is coated with multilayers for reflecting the EUV light thereon.

10. The EUV light source device according to claim 3, wherein the debris shield is formed of a thin film containing carbon nanotubes (CNT) or graphene layers made of carbon.

11. The EUV light source device according to claim 4, wherein the nozzle continuously feeds the liquid target in the form of a droplet from top and to bottom.
